(19) United States
(12) Patent Application Publication
(10) Pub. No.: US 2013/0059092 A1
(43) Pub. Date: Mar. 7, 2013

(54) METHOD AND APPARATUS FOR GAS DISTRIBUTION AND PLASMA APPLICATION IN A LINEAR DEPOSITION CHAMBER

(71) Applicants: HEMANT P. MUNGEKAR, Campbell, CA (US); Alexander S. Polyak, San Jose, CA (US); Michael S. Cox, Gilroy, CA (US)

(72) Inventors: HEMANT P. MUNGEKAR, Campbell, CA (US); Alexander S. Polyak, San Jose, CA (US); Michael S. Cox, Gilroy, CA (US)

(73) Assignee: Applied Materials, Inc., Santa Clara, CA (US)

(21) Appl. No.: 13/605,449

(22) Filed: Sep. 6, 2012

Related U.S. Application Data
(60) Provisional application No. 61/531,869, filed on Sep. 7, 2011.

(51) Int. Cl. C23C 16/513; H05H 1/24

(52) U.S. Cl. 427/569; 118/723 R

(57) ABSTRACT

A method and apparatus for processing a substrate is described. One embodiment of the invention provides an apparatus for forming thin films. The apparatus comprises a chamber defining an internal volume, a plasma source disposed within the internal volume, and at least one gas injection source disposed adjacent the plasma source within the internal volume, wherein the at least one gas injection source comprises a first channel and a second channel for delivering gases to the internal volume, the first channel delivering a gas at a first pressure or a first density and the second channel delivering a gas at a second pressure or a second density, the first pressure or the first density being different than the second pressure or the second density.

### CROSS-REFERENCE TO RELATED APPLICATIONS

This application claims benefit of U.S. Provisional Patent Application Ser. No. 61/531,869 (APPM/016580USL), filed Sep. 7, 2011, which is hereby incorporated by reference herein.

### BACKGROUND OF THE INVENTION

1. Field of the Invention

Embodiments described herein relate to a method and apparatus for depositing one or more layers on a substrate, such as a substrate having a large surface area.

2. Description of the Related Art

Photovoltaic (PV) devices or solar cells are devices which convert sunlight into direct current (DC) electrical power. The PV devices are typically formed on substrates having a large surface area. Typically, the substrates include sheets of glass, silicon or other material. Several types of silicon films, including microcrystalline silicon film (μc-Si), amorphous silicon film (a-Si), polycrystalline silicon film (poly-Si) and the like, are sequentially deposited on the substrate to form the PV devices. A transparent conductive film or a transparent conductive oxide (TCO) film may be deposited in or on these silicon films. The deposition of the thin films on the substrate is typically performed by a chemical vapor deposition (CVD) process, a plasma enhanced chemical vapor deposition (PECVD) process, physical vapor deposition (PVD), among other deposition processes.

In conventional deposition systems, precursor gases flow through a gas diffusion plate in a processing chamber to form a thin film on the substrate. The conventional processing chambers are typically configured to perform a single process according to a recipe. The films deposited according to the recipe typically include substantially homogenous properties. Subsequent etching and/or deposition processes are required to change the film properties. However, the subsequent etching or deposition is typically performed in another chamber. Moving the substrate from one chamber to another chamber requires additional handling of the substrate, which may result in damage to the substrate. Additionally, the processing chambers typically operate in near zero pressure or vacuum atmospheres, and transfer between chambers requires some breaking and reestablishment of vacuum. However, the cycling of pressures within the various chambers increases processing time and costs.

Therefore, what is needed is an apparatus and method for forming one or more layers on a substrate in a single processing chamber, to form a coating on the substrate having different properties.

### SUMMARY OF THE INVENTION

The present invention generally relates to methods and apparatus for depositing one or more layers on a substrate having a large surface area and forming a graded film thereon.

One embodiment of the invention provides an apparatus for forming thin films on a substrate. The apparatus comprises a chamber defining an internal volume, a plasma source disposed within the internal volume, and at least one gas injection source disposed adjacent the plasma source within the internal volume, wherein at least one gas injection source comprises a first channel and a second channel for delivering gases to the internal volume, the first channel delivering a gas at a first pressure or a first density and the second channel delivering a gas at a second pressure or a second density, the first pressure or the first density being different than the second pressure or the second density.

Another embodiment of the invention provides an apparatus for forming thin films on a substrate. The apparatus comprises a chamber defining an internal volume, a plasma source disposed within the internal volume, and at least one gas injection source in electrical communication with the plasma source within the internal volume, wherein the at least one gas injection source comprises a first channel for delivering gases to a first portion of the internal volume and a second channel for delivering gases to a second portion of the internal volume, the first channel delivering a gas at a first pressure or a first density and the second channel delivering a gas at a second pressure or a second density, the first pressure or the first density being different than the second pressure or the second density, wherein the first portion is substantially separated from the second portion.

Another embodiment of the invention provides a method for processing a substrate. The method includes transferring a substrate to a processing chamber having an internal volume, transferring the substrate linearly through a first plasma volume formed in the internal volume, the first plasma volume having a first plasma density and/or a first plasma flux, and transferring the substrate linearly through second plasma volume formed in the internal volume, the second plasma volume having a second plasma density and/or a second plasma flux that is different than the first plasma density and/or the first plasma flux to form a graded film on the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is an isometric view of one embodiment of a processing chamber.

FIG. 2 is side cross-sectional view of the processing chamber along section line 2-2 of FIG. 1.

FIG. 3 is a side cross-sectional view of the processing chamber along section 3-3 of FIG. 1.

FIG. 4 is a side cross-sectional view of another embodiment of a processing chamber.

FIG. 5 is a side cross-sectional view of another embodiment of a processing chamber.

FIG. 6 is a side cross-sectional view of another embodiment of a processing chamber.

FIG. 7 is a side cross-sectional view of another embodiment of a processing chamber.

FIG. 8 is a side cross-sectional view illustrating one embodiment of a coating 800 that may be formed using the processing chambers as described herein.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments described herein relate to a methods and an apparatus for processing a substrate having at least one major surface with a large surface area. Embodiments of a processing chamber adapted to deposit materials on the major surface of the substrate are described herein. The substrates as described herein may comprise substrates made of glass, silicon, ceramics, or other suitable substrate material. The processing chamber may be part of a larger processing system having multiple processing chambers and/or treatment stations disposed in a modular, sequential arrangement in a fabrication facility. A commercial apparatus that may benefit from embodiments described herein is the Applied ATON™ deposition system or the Applied BACCINI® cell system available from Applied Materials, Inc., of Santa Clara, Calif.

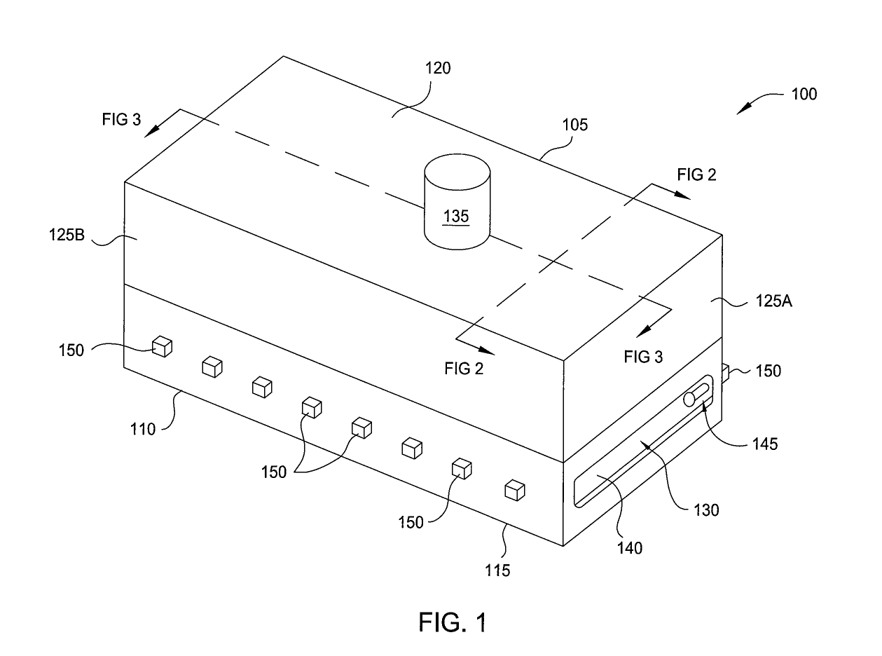

FIG. 1 is an isometric view of one embodiment of a processing chamber 100 used to fabricate photovoltaic devices, liquid crystal displays (LCD's), flat panel displays, or organic light emitting diodes (OLED's). The processing chamber 100 comprises an enclosure 105 comprising one or more walls 110, a bottom 115 and a lid 120. The one or more walls 110 include a first side 125A and a second side 125B. Each of the first side 125A and the second side 125B include a substrate transfer port 130 (only one is shown in FIG. 1). A vacuum pump 135 is shown coupled to the enclosure 105. Each of the substrate transfer ports 130 may be selectively sealed by a door or slit valve device (not shown) to facilitate vacuum pressure in an internal volume 140 of the enclosure 105. The vacuum pump 135 may be a turbomolecular pump adapted to evacuate the internal volume 140 to a pressure of less than 500 milliTorr (mTorr), such as about 10 mTorr to about 100 mTorr, for example, about 10 mTorr to about 20 mTorr. While the vacuum pump 135 is shown coupled to the lid 120, the vacuum pump 135 may be coupled to the bottom 115 or walls 110 in a manner that facilitates evacuation of the internal volume 140.

A movable substrate support assembly comprising a plurality of rotatable substrate supports 145 is disposed in the internal volume 140 (only one is shown in FIG. 1). In the embodiment shown, each of the rotatable substrate supports 145 are coupled through the walls 110 to a support assembly 150. While not shown, the rotatable substrate supports 145 may be coupled to the bottom 115 of the enclosure 105. Each of the support assemblies 150 facilitate rotation and support of the rotatable substrate supports 145. The support assemblies 150 may be a bearing device, an actuator, and combinations thereof. The support assemblies 150 may also insulate the rotatable substrate supports 145 from the enclosure 105 in order to electrically isolate the rotatable substrate supports 145 from the enclosure 105.

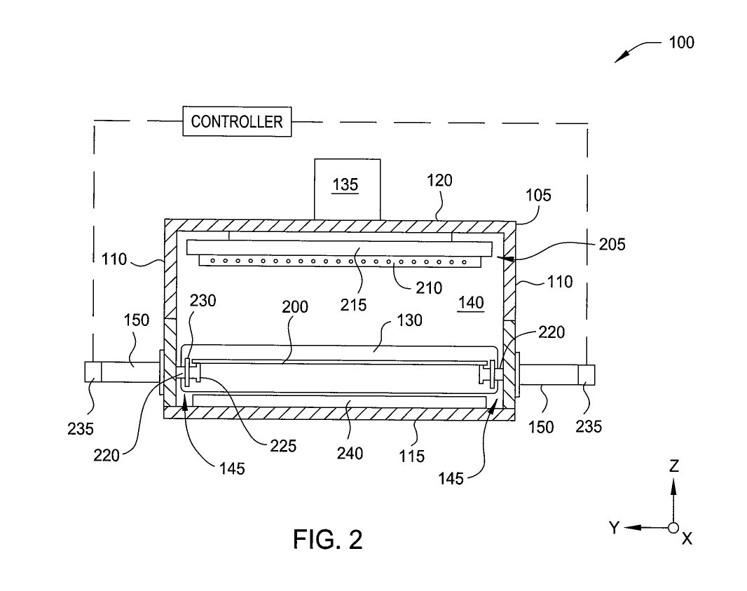

FIG. 2 is side cross-sectional view of the processing chamber 100 along section line 2-2 of FIG. 1. The processing chamber 100 includes pairs of rotatable substrate supports 145 disposed on opposing walls 110 to facilitate support of a substrate 200. The rotatable substrate supports 145 contact opposing edges of the substrate 200 and facilitate movement of the substrate 200 through substrate transfer port 130 and the internal volume 140. For example, the substrate 200 is supported at edge regions thereof and conveyed in the X direction through the internal volume 140 and below a fluid distribution source 205. The fluid distribution source 205 includes a gas manifold 210 and a plasma source 215. As the substrate 200 is disposed in the internal volume 140, gases are dispersed from the gas manifold 210. A plasma of the gases from the gas manifold 210 is ignited by the plasma source 215. A heater plate 240 may be disposed in the internal volume 140 along the bottom 115 of the processing chamber 100.

The plasma source 215 may comprise an inductively coupled plasma source, a microwave generator, a hot wire plasma source, or a capacitively coupled plasma source. The plasma source 215 may also comprise a perforated plate that is coupled to a remote plasma generator for delivering ions generated outside of the processing chamber 100 to the internal volume 140. In one embodiment, the plasma source 215 comprises a linear ion source.

The processing chamber 100 is configured to serially process a plurality of substrates using one or a combination of thermal processes, etching processes, and a plasma enhanced chemical vapor deposition (PECVD) process to form structures and devices on the substrates. In one embodiment, the structures may include one or more junctions used to form part of a thin film photovoltaic device or solar cell. In another embodiment, the structures may be a part of a thin film transistor (TFT) used to form a LCD or TFT type device.

During a deposition or etching process, the rotatable substrate supports 145 may support the substrate 200 in a stationary position below the fluid distribution source 205 or facilitate movement of the substrate 200 relative to the fluid distribution source 205. The rotatable substrate supports 145 include a shaft 220 extending from an opening in the walls 110. The shaft 220 is coupled to the support assembly 150. The shaft 220 includes at least one or more guide members, such as a support wheel 225 and a guide wheel 230. Each support wheel 225 is configured to support a bottom edge of the substrate 200 as the substrate 200 is disposed in the internal volume 140. The shaft 220 may be made of an insulating material to electrically isolate the support wheel 225 and/or the guide wheel 230 from the enclosure 105. The guide wheel 230 facilitates alignment of the substrate 200 by contact with the edges of the substrate 200. The guide wheel 230 includes a diameter greater than a diameter of the support wheel 225 to extend slightly above the plane of the surface of the substrate 200. Each of the support wheel 225 and guide wheel 230 may be fabricated from process resistant materials, such as polymers, for example polyetheretherketone (PEEK) or polyphenylene sulfide (PPS).

The rotatable substrate supports 145 may be disposed in a substantially facing relationship in the Y direction or be staggered along a length of each of the walls 110. While not shown, the support wheels 225 of opposing rotatable substrate supports 145 may be connected by a tubular member to facilitate support of the substrate 200 in the Y direction. Alternatively, one or more support wheels (not shown) may disposed on the bottom 115 of the enclosure 105 below the substrate 200 and between the support wheels 225 in the Y direction to provide support of the center portion of the substrate 200.

At least one of the support assemblies 150 include an actuator 235. Other support assemblies 150 may be adapted as idlers. The actuator 235 is adapted to rotate the shaft 220 and at least the support wheel 225 to move the substrate 200. In one embodiment, at least one pair of opposing support assemblies 150 include the actuator 235. The actuators 235 are in communication with a controller that facilitates synchronized rotation of the support wheels 225 on each of the shafts 220, which provides equalized force to each side of the substrate 200 and prevents misalignment of the substrate 200 during movement. In another embodiment, two or more of the support wheels 225 may be coupled together by a belt or a chain to facilitate synchronized movement of the support wheels 225.

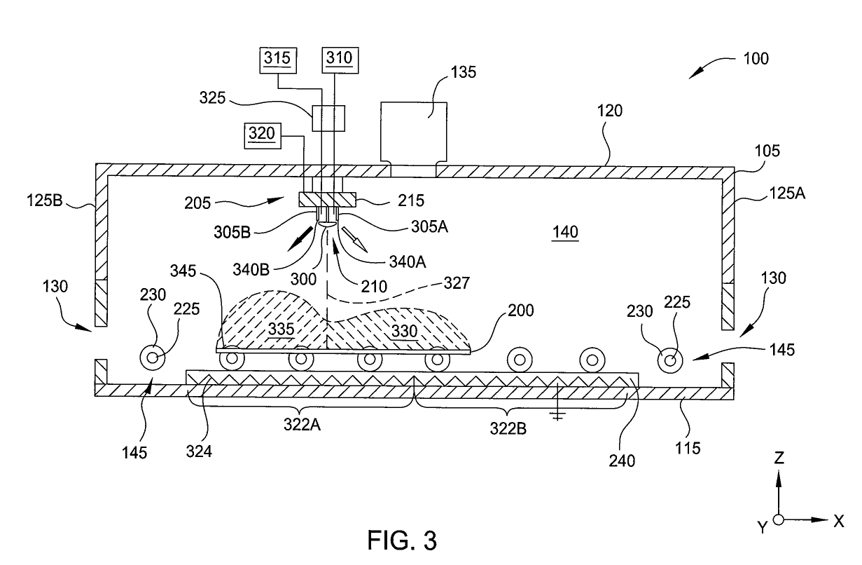

FIG. 3 is a side cross-sectional view of the processing chamber 100 along section line 3-3 of FIG. 1. The fluid distribution source 205 further comprises a dual gas injection manifold 300 having two discrete channels 305A and 305B formed therein. The channel 305A is coupled to a first gas source 310 and the channel 305B is coupled to a second gas source 315. The first gas source 310 and the second gas source 315 are generally configured to deliver one or more precursor gases or carrier gases to the dual gas injection manifold 300. The first gas source 310 and the second gas source 315 may comprise silane (SiH₄), ammonia (NH₃), nitrogen (N₂), hydrogen (H₂), and combinations thereof or derivatives thereof. The plasma source 215 is coupled to a power source 320. The heater plate 240 is shown disposed below the substrate 200. The heater plate 240 may include a heating device 324, such as resistive heating element or a fluid channel. The heater plate 240 is positioned proximal to the substrate 200 in order to heat the substrate 200 to a temperature of about 400 degrees C. to about 550 degrees C. during processing. The heater plate 240 may include one or more zones, such as a first heater zone 322A and a second heater zone 322B. The heater zones 322A, 322B are utilized to provide a temperature gradient therein that is utilized to provide a temperature gradient in the substrate 200 during a deposition and/or etch process. The heater plate 240 may be fabricated from an electrically conductive material to function as a ground or radio frequency (RF) electrode to facilitate a capacitively coupled plasma.

The first gas source 310 and the second gas source 315 are coupled to a controller 325. The controller 325 may comprise a series of controlled valves or mass flow controllers configured to control the flow rate of the precursor gases from the first gas source 310 and the second gas source 315 to the gas injection manifold 300. Each of the channels 305A, 305B include a plurality of nozzles 340A and 340B, respectively, for flowing the respective gases to the internal volume 140. The plurality of nozzles 340A may be of a different size and/or density than the plurality of nozzles 340B. The flow rate of the gases delivered from the first gas source 310 and the second gas source 315 can each be separately controlled to provide a desired gas composition to be delivered from the channel 305A or the channel 305B. The gases from each of the nozzles 340A and 340B may be sequentially pulsed to alternate precursor gases (or different concentrations of gases) for deposition and/or pulses of etchant gases between, or partially overlapping with, pulses of precursor gases.

The fluid distribution source 205 is configured to deliver a non-symmetric fluid distribution and/or gas composition to the space within the internal volume 140 to create non-uniform deposition on the surface area of the substrate 200 as the substrate 200 is moved relative to the fluid distribution source 205 to provide sequential layers and/or alter films on the substrate 200. Due to the configuration of one or a combination of the channels 305A and 305B, the configuration of the plasma source 215, and a temperature gradient provided by the heater zones 322A, 322B, the internal volume 140 may be effectively split into two or more regions, thus allowing the process variables in each region to be varied and controlled independently. In one example, the internal volume 140 may be divided into two sections that are separated by an imaginary vertical plane 327 (e.g., substantially parallel to the Y-Z plane in FIG. 3). In one configuration of the processing chamber 100, the fluid distribution source 205 is configured to divide the internal volume 140 above the substrate 200 into a first plasma volume 330 and a second plasma volume 335 separated by the imaginary vertical plane 327.

In one aspect, the first plasma volume 330 differs from the second plasma volume 335 by properties of the plasma created by the fluid distribution source 205. For example, the first plasma volume 330 may have a lower plasma density (i.e., ions per unit area), a lower flux (i.e., ion density per unit area/time), or combinations thereof, as compared to the second plasma volume 335. Alternatively, the second plasma volume 335 may have a lower plasma density and/or a lower flux than the first plasma volume 330. Due to the configuration of the fluid distribution source 205 and the separation of the internal volume 140 into the first plasma volume 330 and the second plasma volume 335, a user may vary the deposition and/or etch process parameters, which, in one embodiment, facilitates formation of a film having a graded composition on the substrate 200.

In one embodiment, the pressure in the internal volume 140 can be adjusted by the vacuum pump 135 to provide a desired gas flow regime in the internal volume 140 to enhance the quality or properties of the deposited film. In one example, a low pressure is provided in the internal volume 140 (e.g., less than about 500 milliTorr) to provide a laminar flow of reactants (e.g., precursor gases and/or etch gases) and also prevent the amount of mixing of reactants between the first plasma volume 330 and the second plasma volume 335 across the imaginary vertical plane 327. Additionally, the nozzles 340A, 340B may be positioned to direct the flow of gases towards different regions of the substrate 200. In one embodiment, the nozzles 340A, 340B include a plurality of openings that are formed at an angle of about 30 degrees to about 45 degrees relative to the imaginary vertical plane 327 (e.g., either in the −X direction or the +X direction). The temperature of the substrate 200 may also be different in the plasma volumes 330, 335 facilitated by the heater zones 322A and 322B.

Therefore, the fluid distribution source 205 can be used to form a graded film 345 that may consist of a single film layer that has regions having a different chemical composition and/or crystal structure. In one embodiment, the graded film 345 may have regions with differing chemical compositions and/or crystal structure in a direction that is parallel to the deposited film thickness (e.g., parallel to the Z direction in FIG. 3). The graded film 345 may consist of layers that are deposited one after the other as the substrate 200 moves in the X direction relative to the fluid distribution source 205. The deposition of each layer, or a portion of a layer, is temporally separated due to the orientation of the nozzles 340A, 340B and the speed of the substrate 200 as the substrate 200 moves relative to the fluid distribution source 205. The graded film 345 may be formed by the same or different precursors alone, or in combination with sequential or intermittent pulses of etching gases. The graded film 345 may be formed by temperature gradients in the substrate 200 alone or in combination with intermittent or continuous pulses of precursor gases and/or etchant gases. In one embodiment, the graded film 345 may be one or more layers of hydrogenated silicon nitride (Si_{X}N_{Y}:H) having different concentrations of hydrogen and/or Si:N bonds throughout. In another embodiment, the graded film 345 may be an oxide, such as aluminum oxide (Al_{X}O_{Y}), having different stoichiometry, such as differing ratios of aluminum to oxygen (e.g., the ratios of _{X} and _{Y} being greater than, less than, or equal to the stoichiometric ratio). In another embodiment, the graded film 345 may be a nitride, such as silicon nitride (Si_{X}N_{Y}), having different stoichiometry, such as differing ratios of silicon to nitrogen (e.g., the ratios of _{X} and _{Y} being greater than, less than, or equal to the stoichiometric ratio). While a slight temporal separation will be encountered by the material layers formed on the substrate 200, a single continuous graded film 345 may be formed on the surface of the substrate 200.

In one example, the substrate 200 may comprise silicon. As the substrate 200 enters the internal volume 140, the leading edge of the substrate 200 enters the first plasma volume 330. The first plasma volume 330 may comprise a plasma containing one or more precursor gases, a first plasma density and/or a first flux to facilitate formation of a first layer at a first deposition rate on the substrate 200. In one example, the first film may be a passivation layer, such as a hydrogenated silicon nitride (Si_{X}N_{Y}:H) film. As the substrate 200 moves in the +X direction, the substrate 200 enters the second plasma volume 335. The second plasma volume 335 may comprise a plasma containing one or more precursor or etchant gases, a second plasma density and/or a second flux to facilitate formation of a second layer on the first layer at a second deposition rate. The second deposition rate may be greater than the first deposition rate. The second plasma density and/or the second flux may be greater than the first plasma density and/or the first flux. In one example, the second film may be a second passivation layer, such as a hydrogenated silicon nitride (Si_{X}N_{Y}:H) film that has different physical, optical and/or electrical properties than the first film. The second film may also be utilized as a diffusion barrier and may be of a lower quality than the first film.

Thus, the graded film 345 is formed on the substrate 200 as the substrate 200 moves in the X direction through the internal volume 140. The graded film 345 may be utilized as an anti-reflective coating in the manufacture of solar cells. Processing parameters may be changed within one or both of the first plasma volume 330 and the second plasma volume 335 to change the composition and/or properties of the graded film 345, which may be utilized to alter the electrical and/or optical properties of the anti-reflective coating.

The graded film 345 may be deposited on the substrate 200 in numerous ways. In one example, the controller 325 may be utilized to provide a first flow rate of precursor gases from the first gas source 310 and a second flow rate of precursor gases from the second gas source 315. In one embodiment, the second flow rate of the precursor gases from the second gas source 315 is greater than the first flow rate of the precursor gases from the first gas source 310. Thus, the first precursor gas is flowed to the internal volume 140 at a higher rate than the second precursor gas, which provides a higher plasma density and/or a higher flux in the second plasma volume 335 as compared to the first plasma volume 330. Intermittent pulses of etchant gases may also be provided by one or both of the first gas source 310 and the second gas source 315.

In another embodiment, each of the nozzles 340B may include a smaller opening than the nozzles 340A. The smaller openings in the nozzles 340A versus the size of the openings in the nozzles 340B can increase the density of the precursor gases from the second gas source 315, which provides a higher plasma density and/or a higher flux in the second plasma volume 335 as compared to the first plasma volume 330.

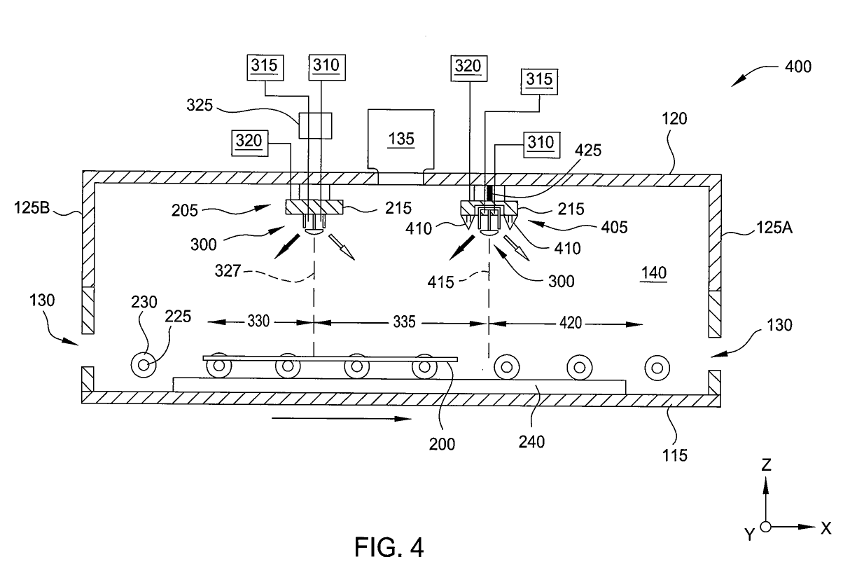

FIG. 4 is a cross-sectional view of another embodiment of a processing chamber 400. The processing chamber 400 is substantially the same as the processing chamber 100 shown in FIGS. 1-3 with the exception of an additional fluid distribution source 405 disposed in the internal volume 140. The processing chamber 400 also includes a fluid distribution source 205 that is substantially similar to the fluid distribution source 205 shown in FIG. 3 with the exception of the first plasma volume 330 and the second plasma volume 335 being on the opposite side of the imaginary vertical plane 327 from the embodiment shown in FIG. 3. The fluid distribution source 405 is substantially the same as the fluid distribution source 205 described in reference to FIG. 3 with the exception of coil elements 410 surrounding a portion of the dual gas injection manifold 300. The coil elements 410 extend from the dual gas injection manifold 300 to oppose each other and focus energy toward an imaginary vertical plane 415 extending from the dual gas injection manifold 300. The imaginary vertical plane 415 may be substantially parallel to the imaginary vertical plane 327.

Each of the coil elements 410 may comprise one or more coils to facilitate formation of an inductively, coupled plasma from the gases delivered from the dual gas injection manifold 300. Alternatively, each of the coil elements 410 may be magnets, conductive coils, and combinations thereof, utilized to form a magnetic field and/or an electrostatic potential that forms a plasma from the gases delivered from the dual gas injection manifold 300.

The combination of the fluid distribution sources 205 and 405 may be utilized to form a graded film on the substrate 200 by facilitating formation of the first plasma volume 330, the second plasma volume 335, and a third plasma volume 420. Each of the first plasma volume 330, the second plasma volume 335, and the third plasma volume 420 may contain a different plasma density and/or a different flux to facilitate formation of at least a first and second layer at different rates on the substrate 200. In one embodiment, one or both of the fluid distribution source 205 and the fluid distribution source 405 may be coupled to an actuator 425 that is movable at least vertically. The actuator 425 may be utilized to adjust spacing between the substrate 200 and the respective dual gas injection manifold 300. This allows additional process control by varying the spacing between the respective dual gas injection manifold 300 and the substrate 200.

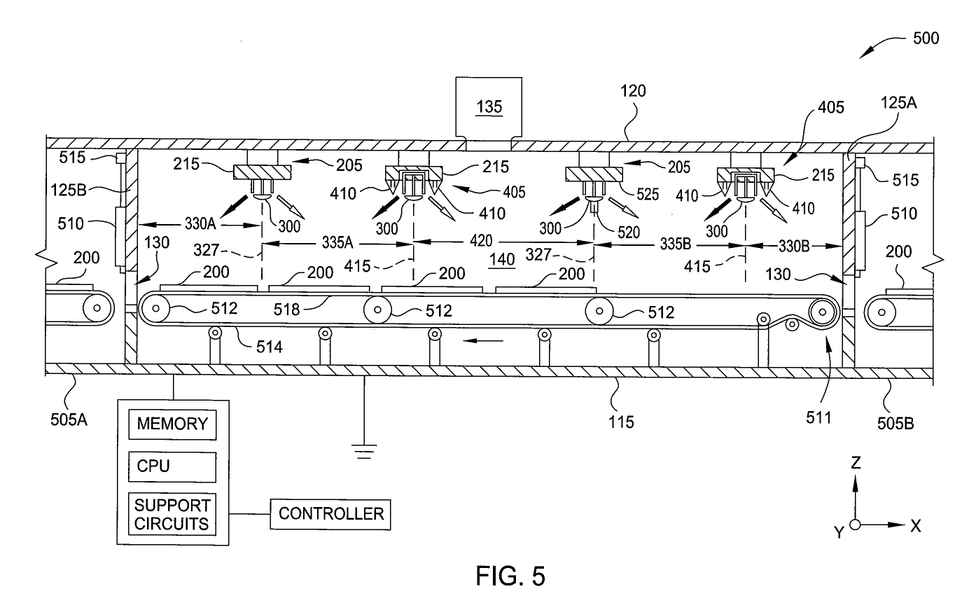

FIG. 5 is a side cross-sectional view of another embodiment of a processing chamber 500 that may form one or more processing chambers in a processing system. Peripheral chambers 505A and 505B may be coupled to the processing chamber 500 to provide a high throughput linear processing system. Each of the peripheral chambers 505A, 505B may be a processing chamber configured to perform the same or different process as the processing chamber 500, a transfer chamber, or other chamber configured to receive, send and/or process a substrate 200.

The processing chamber 500 according to this embodiment comprises one or more fluid distribution sources 205, 405, and a conveyor 511. The conveyor 511 supports and transfers substrates 200 within and through the processing chamber 500. The conveyor 511 may also facilitate transfer of substrates 200 between the processing chamber 500 and the peripheral chambers 505A, 505B through transfer ports 130. The transfer ports 130 include a movable door 510 that is driven to open and close by an actuator 515. The conveyor 511 includes support rollers 512 that support and drive one or more continuous drive members 518 (only one is shown in the side view of FIG. 1). The continuous drive members 518 may comprise an endless drive member, such as a belt, a chain, or a cable. The endless drive member may be fabricated from metallic materials capable of withstanding the processing environment gases and temperatures endured by the substrates 200 during processing, such as stainless steel, aluminum, alloys thereof and combinations thereof. The one or more continuous drive members 518 may be coupled to a supporting material 514 that is configured to support the substrates 200 thereon. In one example, the supporting material 514 comprises a continuous web of material that provides friction between the substrates 200 and the supporting surface thereof, and is capable of withstanding the processing environment gases and temperatures endured by the substrates 200 during processing (e.g., stainless steel mesh, high temperature resistant polymeric materials). The peripheral chambers 505A, 505B may also include a conveyor that is similar to the conveyor 511 shown in the processing chamber 500.

Each of the fluid distribution sources 205, 405 may include the dual gas injection manifold 300 and are configured similar to the fluid distribution sources 205, 405 described in FIGS. 2 and 4, respectively. In one embodiment, at least one of the fluid distribution sources 205, 405 includes a radiant source 520 that is configured to energize one or both of the gases and the substrates 200 to facilitate formation of graded films on the substrates 200. In one configuration, the radiant source 520 includes as an IR lamp(s), tungsten lamp(s), arc lamp(s), microwave heater or other radiant energy source that is configured to deliver energy to a surface of the substrates 200 disposed in the internal volume 140 of the processing chamber 500. In one embodiment, the fluid distribution source 205 includes a reflector 525.

Closing of the doors 510 and actuation of the vacuum pump 135 facilitates vacuum conditions in the internal volume 140 and may facilitate formation of the imaginary vertical planes 327 and 415. The combination of the fluid distribution sources 205 and 405 may be utilized to form a graded film on a plurality of substrates 200 by facilitating formation of a first plasma volume 330A, a second plasma volume 335A, and a third plasma volume 420, as well as a fourth plasma volume 335B and a fifth plasma volume 330B. Each of the first plasma volume 330, the second plasma volume 335, the third plasma volume 420, the fourth plasma volume 335B and a fifth plasma volume 330B may contain a different plasma density and/or a different flux to facilitate formation of layers on the substrate 200. The substrates 200 may be stationary on the conveyor 511 or move incrementally within the internal volume 140 during deposition and/or etching on the substrates 200.

While four substrates 200 are shown, the chamber 500 may be utilized to form graded films on a single substrate as the substrate is moved relative to the fluid distribution sources 205, 405. In one embodiment, the chamber 500 may be provided with two substrates 200 initially positioned on the conveyor 511 at first locations adjacent the first plasma volume 330A and the third plasma volume 420, and the substrates 200 are incrementally moved by the conveyor 511 to second locations through the plasma volumes by rotating the continuous drive members 518 about a one quarter revolution. For example, a first substrate 200 is initially positioned on the conveyor 511 at a first location adjacent the first plasma volume 330A (i.e., left hand side of the conveyor 511) while a second substrate 200 is initially positioned at a second location adjacent the third plasma volume 420 (i.e., near center of the conveyor 511). By actuating the conveyor 511 a one quarter revolution, the first substrate 200 and the second substrate 200 move through adjacent plasma volumes in the X direction to second locations where the rotation of the conveyor 511 may be stopped. In this example, the second location of the first substrate 200 would be adjacent the third plasma volume 420 (i.e., near center of the conveyor 511) while the second location of the second substrate 200 would be adjacent the fifth plasma volume 330B (i.e., near the right side of the conveyor 511). Movement of the conveyor 511, as well as operation of other components disposed in or on the chamber 500, may be controlled by a controller.

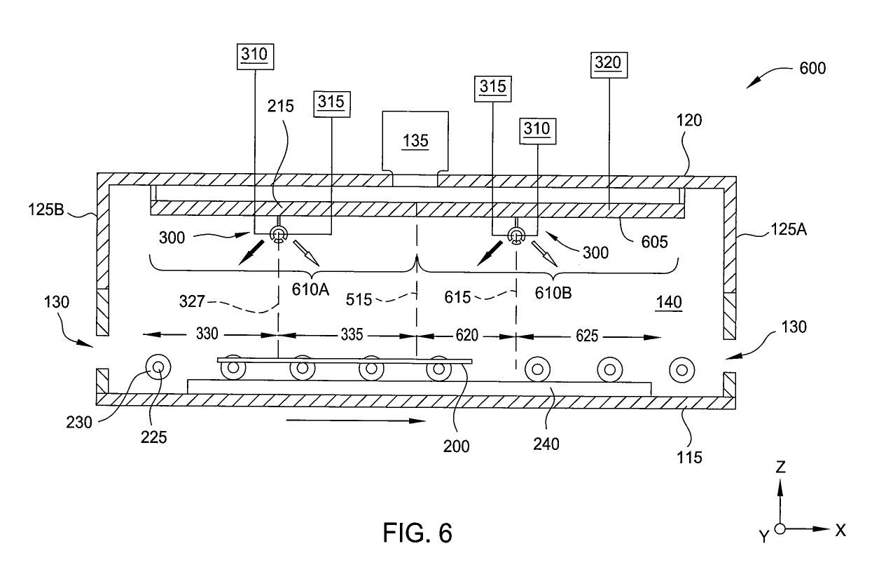

FIG. 6 is a cross-sectional view of another embodiment of a processing chamber 600. In this embodiment, a common plasma source 605 is shown in the internal volume 140. Two dual gas injection manifolds 300 are shown in the internal volume 140 below the common plasma source 605. While two dual gas injection manifolds 300 are shown, the processing chamber 600 may include more than two dual gas injection manifolds 300 disposed below the common plasma source 605.

The common plasma source 605 includes a length (X direction) and/or a width (Y direction) that substantially spans the length (X direction) and/or width (Y direction) of the internal volume 140. The common plasma source 605 may comprise an inductively coupled plasma source, a microwave generator, a hot wire plasma source, or a capacitively coupled plasma source. The common plasma source 605 may also comprise a perforated plate that is coupled to a remote plasma generator for delivering ions generated outside of the processing chamber 600 to the internal volume 140. In one embodiment, the common plasma source 605 comprises a linear ion source.

The common plasma source 605 is coupled to the power source 320. In one embodiment, the power source 320 is operable to vary power to portions of the common plasma source 605 to control the plasma generation thereof. For example, the common plasma source 605 may comprise zones, such as a first zone 610A and a second zone 610B, where power is varied or tuned to create different frequencies in the first zone 610A and the second zone 610B. The first zone 610A and the second zone 610B may separate the internal volume into two regions that are divided by an imaginary vertical plane 615. The imaginary vertical plane 615 may be parallel to the imaginary vertical plane 327 (shown in FIG. 3).

In one aspect, the dual gas injection manifold 300 disposed below the first zone 610A of the common plasma source 605 may be utilized to form a layer or layers on the substrate 200 by facilitating formation of the first plasma volume 330 and the second plasma volume 335. Likewise, the dual gas injection manifold 300 disposed below the second zone 610B of the common plasma source 605 may be utilized to form additional layers on the substrate 200 by facilitating formation of a third plasma volume 620 and a fourth plasma volume 625. Each of the first plasma volume 330, the second plasma volume 335, the third plasma volume 620, and the fourth plasma volume 625 may contain a different plasma density and/or a different flux to facilitate formation of a first layer, a second layer, a third layer and a fourth layer at different rates on the substrate 200. While a slight temporal separation will be encountered by the material layers formed on the substrate 200, a single continuous graded film may be formed on the surface of the substrate 200. While the embodiment described above utilizes varied plasma from the common plasma source 605, it is contemplated that the first plasma volume 330, the second plasma volume 335, the third plasma volume 620, and the fourth plasma volume 625 may be provided by the common plasma source 605 without the need to vary the power to the common plasma source 605. For example, the low pressure in the internal volume 140 may be utilized to reduce mixing of reactants between the second plasma volume 335 and the third plasma volume 620, thus separating the second plasma volume 335 and the third plasma volume 620 along the imaginary vertical plane 615 without varying power to the common plasma source 605.

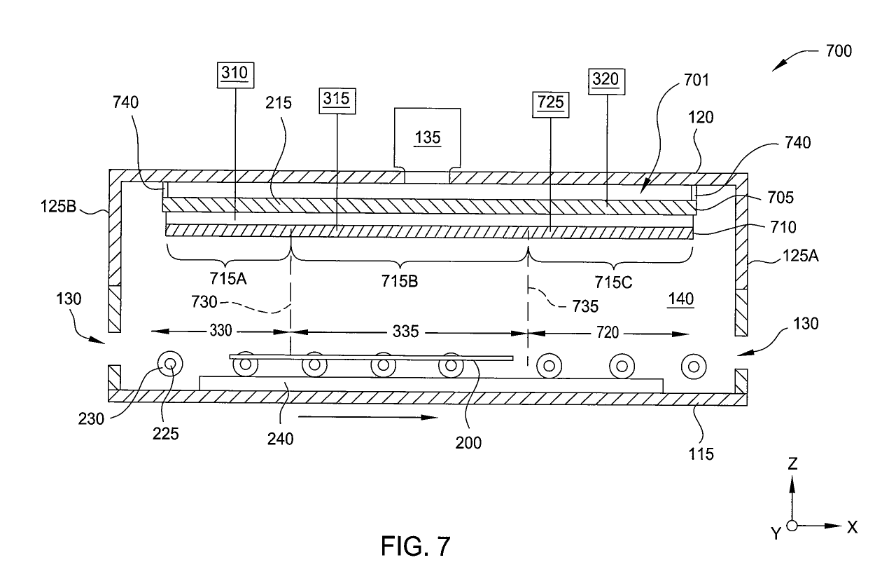

FIG. 7 is a cross-sectional view of another embodiment of a processing chamber 700. In this embodiment, a linear fluid distribution source 701 is disposed in the internal volume along a longitudinal axis of the processing chamber 700. The linear fluid distribution source 701 comprises a common plasma source 705 and a gas distribution source 710. The common plasma source 705 includes a length (X direction) and/or a width (Y direction) that substantially spans the length (X direction) and/or width (Y direction) of the internal volume 140. The common plasma source 705 may comprise an inductively coupled plasma source, a microwave generator, a hot wire plasma source, or a capacitively coupled plasma source. The common plasma source 705 may also comprise a perforated plate that is coupled to a remote plasma generator for delivering ions generated outside of the processing chamber 700 to the internal volume 140. In one embodiment, the common plasma source 705 comprises a linear ion source.

The gas distribution source 710 is constructed to allow energy from the common plasma source 705 to couple with gases delivered from the gas distribution source 710 to the internal volume 140. For example, the gas distribution source 710 may comprise a perforated plate or a plurality of tubular conduits disposed along the length of the internal volume 140.

In one embodiment, the gas distribution source 710 is partitioned into zones, such as a first zone 715A, a second zone 715B and a third zone 715C operable to deliver different precursor and/or etchant gases and/or different flow rates of precursor and/or etchant gases. Each of the first zone 715A, the second zone 715B and the third zone 715C may be utilized to form the first plasma volume 330 with precursor and/or etchant gases from the first gas source 310, the second plasma volume 335 from precursor and/or etchant gases from the second gas source 315, and a third plasma volume 720 with precursor and/or etchant gases from a third gas source 725. The third gas source 725 may comprise the same gases as the first gas source 310 and the second gas source 315. In one embodiment, one or both of the gas distribution source 710 and the common plasma source 705 may be substantially parallel to the plane of the substrate travel path (e.g., parallel to the X-Y plane). In another embodiment, one or both of the gas distribution source 710 and the common plasma source 705 may be angled relative to the plane of the substrate travel path, which allows a variable spacing between the linear fluid distribution source 701 and the surface of the substrate 200. For example, one or both ends of the linear fluid distribution source 701 may be coupled to an actuator 740 that varies the angle of the linear fluid distribution source with respect to the plane of the substrate travel path. The actuators 740 may also be used to raise or lower the linear fluid distribution source 701 in a manner that is substantially parallel to the surface of the substrate 200 in order to vary the spacing therebetween. The use of the actuators 740 allows additional process control by varying the spacing and/or the angular relationship between the linear fluid distribution source 701 and the surface of the substrate 200.

A first layer may be formed on the substrate 200 as the substrate 200 moves through the first plasma volume 330 and a second layer may be formed on the first layer as the substrate 200 moves through the second plasma volume 335. Temperature variations and/or low pressure in the internal volume 140 may separate the first plasma volume 330 and the second plasma volume 335 along an imaginary vertical plane 730. A third layer may be formed on the second layer as the substrate 200 moves through the third plasma volume 720 and the low pressure in the internal volume 140 may separate the second plasma volume 335 and the third plasma volume 720 along an imaginary vertical plane 735. While a slight temporal separation will be encountered by the material layers formed on the substrate 200, a single continuous graded film may be formed on the surface of the substrate 200 as the substrate 200 moves through the plasma volumes 330, 335 and 720.

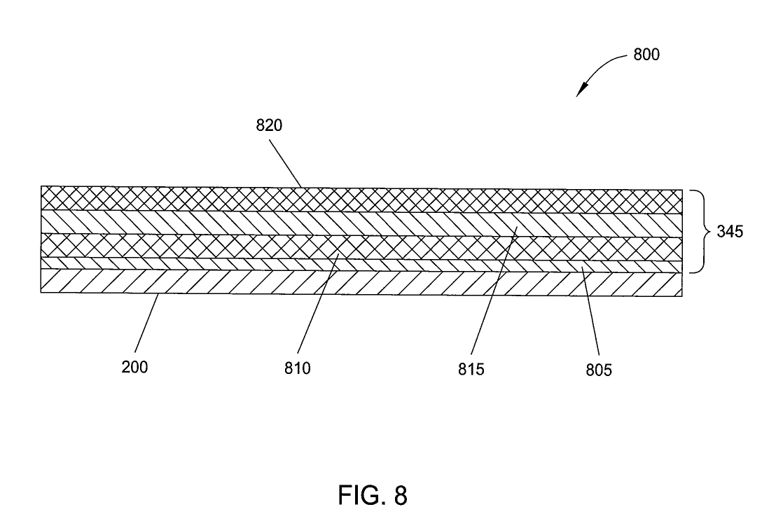

FIG. 8 is a side cross-sectional view illustrating one embodiment of a coating 800 that may be formed using the chambers 100, 400, 500, 600 or 700 as described herein. The coating 800 comprises a graded film 345 formed on a substrate 200. The substrate 200 may comprise a silicon wafer. The graded film includes, at least, a first layer 805, a second layer 810, a third layer 815 and a fourth layer 820. Each of the first layer 805, the second layer 810, the third layer 815 and the fourth layer 820 may comprise the same material having different properties and/or different compositions. In one embodiment, each of the first layer 805, the second layer 810, the third layer 815 and the fourth layer 820 comprise an oxide or a nitride, such as silicon nitride (Si_{X}N_{Y}). Each of the first layer 805, the second layer 810, the third layer 815 and the fourth layer 820 include different densities to provide different optical properties. For example, the first layer 805 may comprise a nitride seed layer having a first density and the second layer 810 may comprise a nitride layer having a second density that is greater than the first density. The third layer 815 may comprise a nitride layer having a third density and the fourth layer 820 may comprise a nitride layer having a fourth density that is greater than the third density. The densities of the first layer 805 and the third layer 815 may be substantially equal while the densities of the second layer 810 and the fourth layer 820 may be substantially equal.

While the foregoing is directed to embodiments of the present invention, other and further embodiments of the invention may be devised without departing from the basic scope thereof, and the scope thereof is determined by the claims that follow.

1. An apparatus for forming thin films on a substrate, comprising:
a chamber defining an internal volume;
a plasma source disposed within the internal volume; and
at least one gas injection source disposed adjacent the plasma source within the internal volume, wherein the at least one gas injection source comprises a first channel and a second channel for delivering gases to the internal volume, the first channel delivering a gas at a first pressure or a first density and the second channel delivering a gas at a second pressure or a second density, the first pressure or the first density being different than the second pressure or the second density.

2. The apparatus of claim 1, wherein the plasma source is electrically coupled to the at least one gas injection source.

3. The apparatus of claim 1, wherein the at least one gas injection source comprises a plurality of coil elements that are in communication with the plasma source.

4. The apparatus of claim 1, wherein the at least one gas injection source comprises two gas injection sources.

5. The apparatus of claim 4, wherein each of the gas injection sources are electrically coupled to a respective plasma source.

6. The apparatus of claim 4, wherein each of the gas injection sources share a common plasma source.

7. The apparatus of claim 1, wherein the at least one gas injection source is disposed along the length of the chamber.

8. The apparatus of claim 1, further comprising:
a movable substrate support assembly disposed along a longitudinal axis of the chamber.

9. The apparatus of claim 8, wherein the movable substrate support assembly comprises a plurality of rotatable substrate supports disposed in an opposing relationship in the internal volume.

10. An apparatus for forming thin films on a substrate, comprising:
a chamber defining an internal volume;
a plasma source disposed within the internal volume;
a movable substrate support assembly disposed in the internal volume; and
at least one gas injection source in electrical communication with the plasma source within the internal volume, wherein the at least one gas injection source comprises a first channel for delivering gases to a first portion of the internal volume and a second channel for delivering gases to a second portion of the internal volume, the first channel for delivering a gas at a first pressure or a first density and the second channel for delivering a gas at a second pressure or a second density, the first pressure or the first density being different than the second pressure or the second density, wherein the first portion is substantially separated from the second portion.

11. The apparatus of claim 10, wherein the at least one gas injection source is positioned orthogonally to a longitudinal axis of the chamber.

12. The apparatus of claim 11, wherein the at least one gas injection source comprises two gas injection sources.

13. The apparatus of claim 10, wherein the at least one gas injection source is positioned along a longitudinal axis of the chamber.

14. The apparatus of claim 13, wherein the at least one gas injection source comprises a dimension that spans a width or a length of the internal volume.

15. A method for processing a substrate, comprising:
transferring a substrate to a processing chamber having an internal volume;
transferring the substrate linearly through a first plasma volume formed in the internal volume, the first plasma volume having a first plasma density and/or a first plasma flux; and
transferring the substrate linearly through second plasma volume formed in the internal volume, the second plasma volume having a second plasma density and/or a second plasma flux that is different than the first plasma density and/or the first plasma flux to form a graded film on the substrate.

16. The method of claim 15, wherein the first plasma volume and the second plasma volume are formed by a common plasma source.

17. The method of claim 16, wherein the common plasma source is substantially parallel to the substrate surface.

18. The method of claim 15, wherein the first plasma volume and the second plasma volume are formed by a common gas injection source.

19. The method of claim 18, wherein the common gas injection source is substantially parallel to the substrate surface.

20. The method of claim 18, wherein the common gas injection source is angled relative to the substrate surface.
